(19) United States
(12) Patent Application Publication
(10) Pub. No.: US 2007/0121279 A1
(43) Pub. Date: May 31, 2007

(54) Translating axes slide mechanism

(75) Inventors: William H. Robertson JR., Fort Lauderdale, FL (US); Donald W. Burnette, Sunrise, FL (US); Julio C. Castaneda, Coral Springs, FL (US); Francis M. Staszesky, Fort Laurderdale, FL (US)

Correspondence Address: AKERMAN SENTERFITT, P.O. BOX 3188, WEST PALM BEACH, FL, 33402-3188, US

(73) Assignee: Motorola, Inc., Schaumburg, IL (US)

(21) Appl. No.: 11/286,745

(22) Filed: Nov. 25, 2005

(51) Int. Cl. H05K 5/00; H04M 1/00

(52) U.S. Cl. 361/679; 455/575.1; 455/575.9

(57) ABSTRACT

An electronic product (10) includes a front housing (12) coupled to a first frame (32) having a first frame guide rail (34), a rear housing (14) coupled to a second frame (42) having a second frame guide rail (54), a pivot arm (50) coupled between a fixed axis (33) on the first frame and a first translating axis (45) on the second frame, and a second translating axis (46) that translates along the first frame guide rail as the first translating axis translates along the second frame guide rail. The fixed axis and second translating axis are in substantially the same horizontal plane when the electronic product is in a closed position. The fixed axis and first translating axis are in substantially the same horizontal plane when the electronic product is in a closed position and in substantially the same vertical plane when the electronic product is an open position.

### FIELD

This invention relates generally to sliding mechanisms, and more particularly to a sliding mechanism having multiple translating axes.

### BACKGROUND

Slider phones typically slide in one direction and in one plane while opening or closing. This form factor can make for discomfort on the face while using the phone. Other proposed devices having sliding mechanisms include a couple of fixed axes and a single translating axis. Such arrangement creates a device having an overall thickness that is not necessarily desirable. Slider phones also typically have an antenna that is in closer proximity to the users head due to their form factor over flip phones.

### SUMMARY

Embodiments in accordance with the present invention can provide a sliding mechanism having multiple translating axes that enable products having desirable form factors.

In a first embodiment of the present invention, a slide mechanism can include a first frame having a first frame guide rail, a second frame having a second frame guide rail, a pivot arm coupled between a fixed axis on the first frame and a first translating axis on the second frame, and a second translating axis that translates along the first frame guide rail as the first translating axis translates along the second frame guide rail. The slide mechanism can further include a follower coupled to the first translating axis that slides along the second frame guide rail as the second translating axis slides along the first frame guide rail. The slide mechanism can further include a spring biasing device coupled between the second frame and the follower such as an over-center spring that biases the first frame and second frame in a closed position when on a first side of center and biases the first frame and the second frame in an open position when on a second side of center. Furthermore, the slide mechanism can include a torsion spring coupled on the pivot arm. Note, the fixed axis and the second translating axis can be in substantially the same horizontal plane and vertical plane when the slide mechanism is in a closed position. The fixed axis and the first translating axis can be in substantially the same horizontal plane when the slide mechanism is in a closed position and in substantially the same vertical plane when the slide mechanism is an open position.

In a second embodiment of the present invention, an electronic product can include a front housing coupled to a first frame having a first frame guide rail, a rear housing coupled to a second frame having a second frame guide rail, a pivot arm coupled between a fixed axis on the first frame and a first translating axis on the second frame, and a second translating axis that translates along the first frame guide rail as the first translating axis translates along the second frame guide rail. The electronic product can be any number of devices including, but not limited to a cellular phone, a satellite phone, a smart phone, a personal digital assistant, a laptop computer, a remote control apparatus, a satellite radio, a messaging device, or a satellite positioning system receiver.

The electronic product can further include a display mounted in the front housing and a keypad mounted in the rear housing. A follower can be coupled to the first translating axis that slides along the second frame guide rail as the second translating axis slides along the first frame guide rail. A spring biasing device can be coupled between the second frame and the follower, where the spring biasing device is an over-center spring that biases the first frame and second frame in a closed position when on a first side of center and biases the first frame and the second frame in an open position when on a second side of center. The electronic product can further include a torsion spring coupled on the pivot arm. The front housing can cover a keypad on the rear housing in a closed position and expose the keypad in an opened position. The front housing slides in at least two dimensions when traversing from a closed position to an open position or from the open position to the closed position. Note, the fixed axis and the second translating axis can be in substantially the same horizontal and vertical planes when the electronic product is in a closed position. Also note that fixed axis and the first translating axis can be in substantially the same horizontal plane when the electronic product is in a closed position and in substantially the same vertical plane when the electronic product is an open position.

In a third embodiment of the present invention, a method of sliding a first housing portion in two dimensions relative to a second housing portion can include the steps of coupling a pivot arm between a fixed axis on a first frame of the first housing portion and a first translating axis on a second frame of the second housing portion and translating a second translating axis along a first frame guide rail of the first frame as the first translating axis translates along a second frame guide rail of the second frame.

The terms “a” or “an,” as used herein, are defined as one or more than one. The term “plurality,” as used herein, is defined as two or more than two. The term “another,” as used herein, is defined as at least a second or more. The terms “including” and/or “having,” as used herein, are defined as comprising (i.e., open language). The term “coupled,” as used herein, is defined as connected, although not necessarily directly, and not necessarily mechanically.

### BRIEF DESCRIPTION OF THE DRAWINGS

FIG. 1 is a front perspective view of an electronic device in a closed position in accordance with an embodiment of the present invention.

FIG. 2 is a front perspective view of the electronic device of FIG. 2 in an open position in accordance with an embodiment of the present invention.

FIG. 3 is a front perspective view of the slide mechanism in a closed position in accordance with an embodiment of the present invention.

FIG. 4 is a front perspective view of the slide mechanism in an open position in accordance with an embodiment of the present invention.

FIG. 5 is a rear perspective view of the slide mechanism in a closed position in accordance with an embodiment of the present invention.

FIG. 6 is a rear perspective view of the slide mechanism in an open position in accordance with an embodiment of the present invention.

FIG. 7 is a side view of the slide mechanism in a closed position in accordance with an embodiment of the present invention.

FIG. 8 is a side view of the slide mechanism in an open position in accordance with an embodiment of the present invention.

FIG. 9 is a flow chart illustrating a method of sliding a first housing portion in two dimensions relative to a second housing portion in accordance with an embodiment of the present invention.

### DETAILED DESCRIPTION OF THE DRAWINGS

While the specification concludes with claims defining the features of embodiments of the invention that are regarded as novel, it is believed that the invention will be better understood from a consideration of the following description in conjunction with the figures, in which like reference numerals are carried forward.

A slider phone in accordance with the embodiments herein can have a two (2) dimensional path instead of a one (1) dimensional path like those found in existing slider phones. The embodiments illustrated can include multiple translating axes and one fixed axis. One moving piece travels up for a predetermined distance relative to another piece such as 25 mm, and then engages a pivot arm which swings one of the moving pieces up to a predetermined angle such as 15 degrees, while continuing to travel up in a Y or vertical direction another predetermined distance such as 20 mm. Such arrangement allows for more comfort on the face of the user and can be more contoured to the user's head. Such arrangement can also increase the distance from the user's head to an antenna on a device having an antenna using such sliding mechanism.

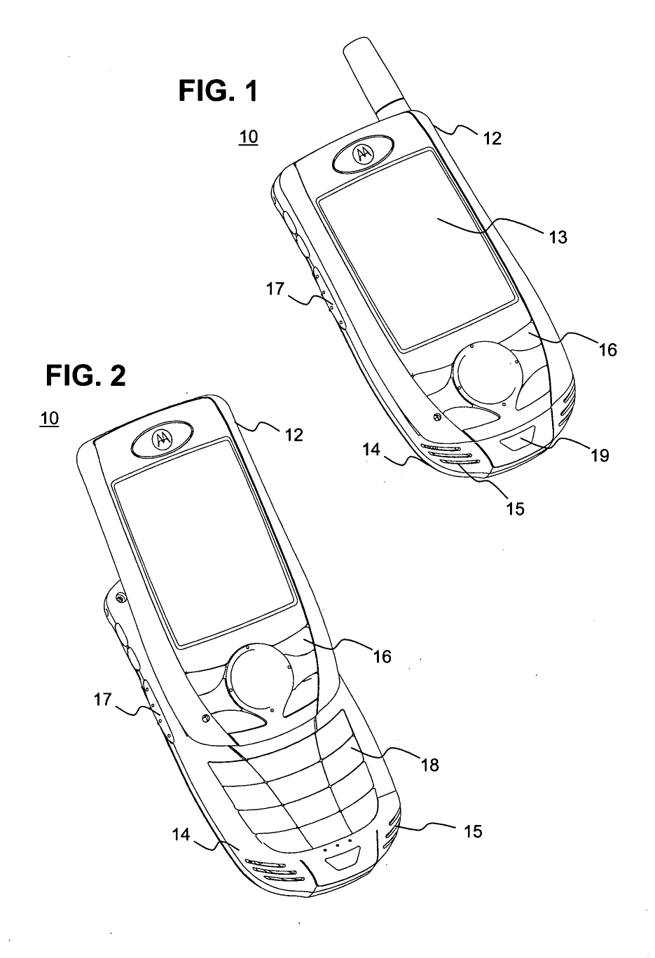

Referring to FIGS. 1 and 2, perspective views of an electronic product 10 such as a wireless communication device is shown in closed and open positions respectively. In this particular embodiment, the electronic product 10 can include a top or front housing 12 that can hold a display 13 and keys or a keypad 16. The electronic product 10 can further include a bottom or rear housing 14 that can house a speaker 15, a microphone 19 and other buttons on a side such as a push-to-activate or push-to-talk button 17. Note, when the electronic product 10 is in a closed position as shown in FIG. 1, the keys 18 are not accessible, whereas the keys 18 become accessible when the electronic product 10 is in an open position or when housing 12 slides up (and slightly out) relative to housing 14.

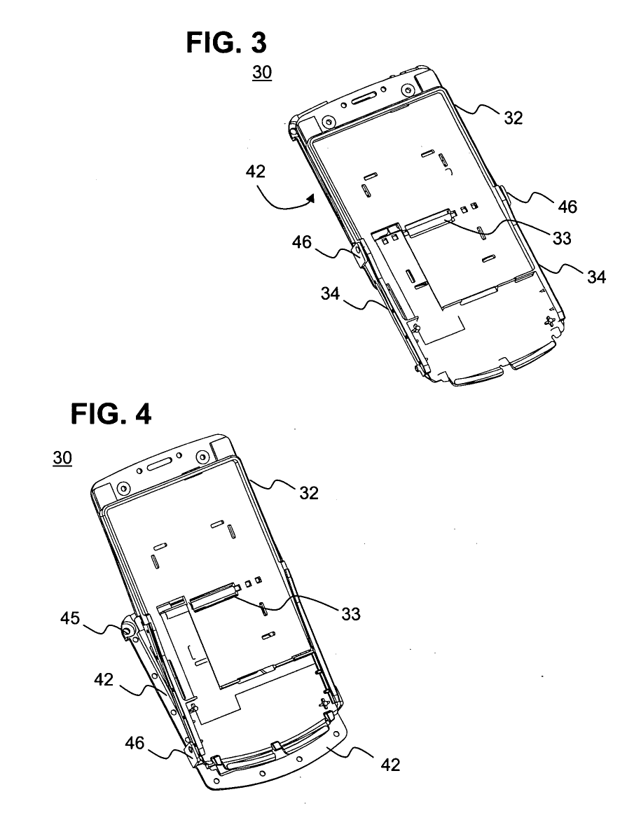

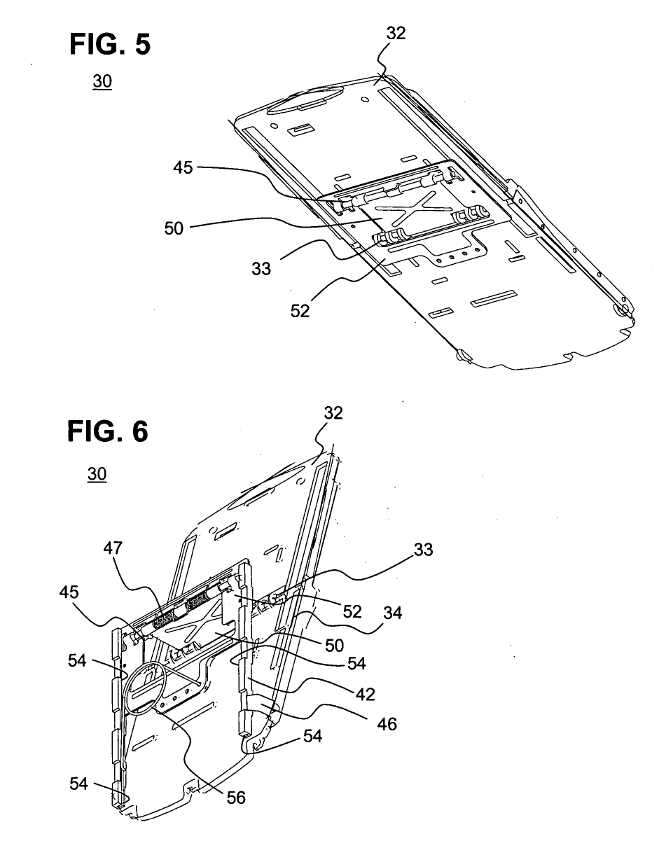

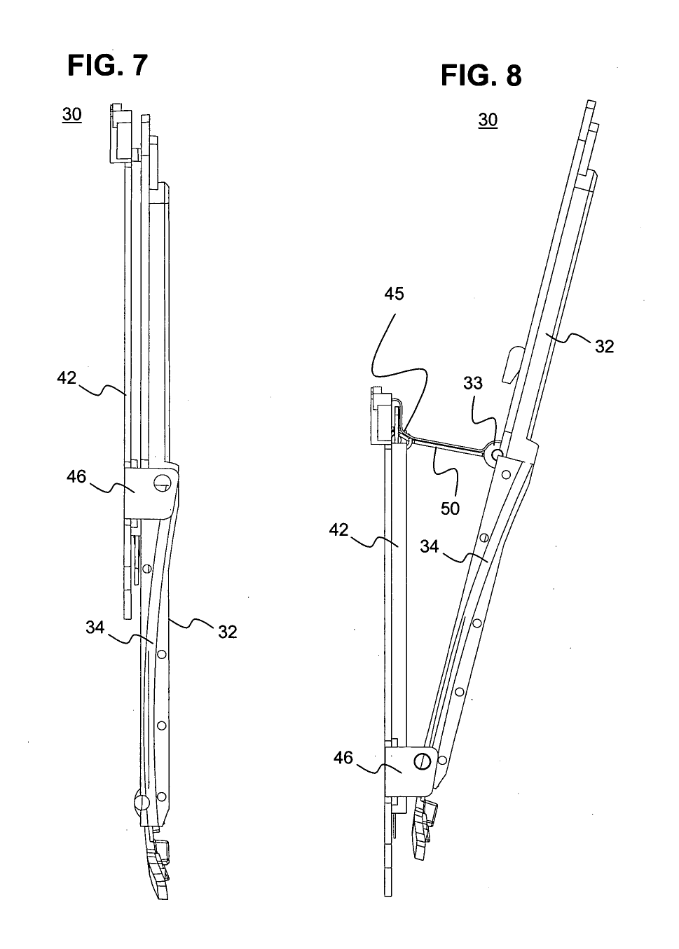

Referring to FIGS. 3 through 6, a slide mechanism 30 housed within the electronic product 10 of FIG. 1 is illustrated in closed and open positions respectively. The slide mechanism 30 can include a first frame 32 having a first frame guide rail 34 (also see FIGS. 7 and 8), a second frame 42 having a second frame guide rail 54 (see also FIG. 6), a pivot arm 50 coupled between a fixed axis (33) on the first frame 32 and a first translating axis 45 on the second frame 42, and a second translating axis 46 that translates along the first frame guide rail 34 as the first translating axis 45 translates along the second frame guide rail 54. The slide mechanism 30 can further include a follower 52 coupled to the first translating axis 45 that slides along the second frame guide rail 54 as the second translating axis 46 slides along the first frame guide rail 34. The slide mechanism 30 can further include a spring biasing device 56 coupled between the second frame 42 and the follower 52 such as an over-center spring that biases the first frame 32 and second frame 42 in a closed position when on a first side of center and biases the first frame and the second frame in an open position when on a second side of center. Furthermore, the slide mechanism 30 can include a torsion spring 47 coupled on the pivot arm 50 as illustrated in FIG. 6. Note, the fixed axis 33 and the second translating axis 46 can be in substantially the same horizontal plane and vertical plane when the slide mechanism is in a closed position. (Note, the second frame 42 is removed and not shown in FIG. 5 for clarity, but would be substantially flush with the first frame 32). The fixed axis 33 and the first translating axis 45 can be in substantially the same horizontal plane when the slide mechanism is in a closed position and in substantially the same vertical plane when the slide mechanism is an open position.

Referring to FIGS. 1-6, the electronic product 10 can include the front housing 12 coupled to the first frame 32 having the first frame guide rail 34, the rear housing 14 coupled to the second frame 42 having the second frame guide rail 54, a pivot arm 50 coupled between a fixed axis 33 on the first frame 32 and a first translating axis 45 on the second frame 42, and a second translating axis 46 that translates along the first frame guide rail 34 as the first translating axis 45 translates along the second frame guide rail 54. The electronic product 10 can be any number of devices including, but not limited to a cellular phone, a satellite phone, a smart phone, a personal digital assistant, a laptop computer, a remote control apparatus, a satellite radio, a messaging device, or a satellite positioning system receiver.

As illustrated electronic product 10 can further include a display 13 mounted in the front housing 12 and a keypad mounted 18 in the rear housing 14. A follower 52 can be coupled to the first translating axis 45 that slides along the second frame guide rail 54 as the second translating axis 46 slides along the first frame guide rail 34. A spring biasing device 56 can be coupled between the second frame 42 and the follower 52, where the spring biasing device 56 is an over-center spring that biases the first frame 32 and second frame 42 in a closed position when on a first side of center and biases the first frame and the second frame in an open position when on a second side of center. The front housing 12 can cover the keypad 18 on the rear housing 14 in a closed position and expose the keypad 18 in an opened position. The front housing 12 slides in at least two dimensions when traversing from a closed position to an open position or from the open position to the closed position.

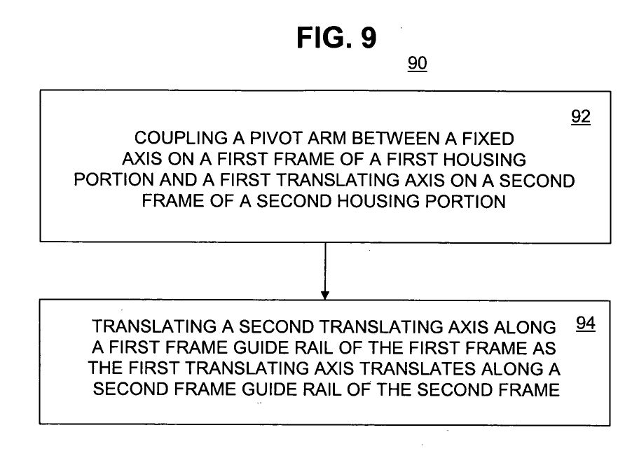

Referring to FIG. 9, a flow chart illustrating a method 90 of sliding a first housing portion in two dimensions relative to a second housing portion can include the step 92 of coupling a pivot arm between a fixed axis on a first frame of the first housing portion and a first translating axis on a second frame of the second housing portion and translating at step 94 a second translating axis along a first frame guide rail of the first frame as the first translating axis translates along a second frame guide rail of the second frame.

In light of the foregoing description, it should also be recognized that embodiments in accordance with the present invention can be realized in numerous configurations contemplated to be within the scope and spirit of the claims. Additionally, the description above is intended by way of example only and is not intended to limit the present invention in any way, except as set forth in the following claims.

What is claimed is:

1. A slide mechanism, comprising:
a first frame having a first frame guide rail;
a second frame having a second frame guide rail;
a pivot arm coupled between a fixed axis on the first frame and a first translating axis on the second frame; and
a second translating axis that translates along the first frame guide rail as the first translating axis translates along the second frame guide rail.

2. The slide mechanism of claim 1, wherein the slide mechanism further comprises a follower coupled to the first translating axis that slides along the second frame guide rail as the second translating axis slides along the first frame guide rail.

3. The slide mechanism of claim 2, wherein the slide mechanism further comprises a spring biasing device coupled between the second frame and the follower.

4. The slide mechanism of claim 3, wherein the spring biasing device is an over-center spring that biases the first frame and second frame in a closed position when on a first side of center and biases the first frame and the second frame in an open position when on a second side of center.

5. The slide mechanism of claim 1, wherein the slide mechanism further comprises a torsion spring coupled on the pivot arm.

6. The slide mechanism of claim 1, wherein the fixed axis and the second translating axis are in substantially the same horizontal plane and vertical plane when the slide mechanism is in a closed position.

7. The slide mechanism of claim 1, wherein the fixed axis and the first translating axis are in substantially the same horizontal plane when the slide mechanism is in a closed position and in substantially the same vertical plane when the slide mechanism is an open position.

8. An electronic product, comprising;
a front housing coupled to a first frame having a first frame guide rail;
a rear housing coupled to a second frame having a second frame guide rail;
a pivot arm coupled between a fixed axis on the first frame and a first translating axis on the second frame; and
a second translating axis that translates along the first frame guide rail as the first translating axis translates along the second frame guide rail.

9. The electronic product of claim 8, wherein the electronic product further comprises a display mounted in the front housing.

10. The electronic product of claim 8, wherein the electronic product further comprises a keypad mounted in the rear housing.

11. The electronic product of claim 8, wherein the electronic product further comprises a follower coupled to the first translating axis that slides along the second frame guide rail as the second translating axis slides along the first frame guide rail.

12. The electronic product of claim 11, wherein the electronic product further comprises a spring biasing device coupled between the second frame and the follower.

13. The electronic product of claim 12, wherein the spring biasing device is an over-center spring that biases the first frame and second frame in a closed position when on a first side of center and biases the first frame and the second frame in an open position when on a second side of center.

14. The electronic product of claim 8, wherein the electronic product further comprises a torsion spring coupled on the pivot arm.

15. The electronic product of claim 8, wherein the electronic product comprises a cellular phone, a satellite phone, a smart phone, a personal digital assistant, a laptop computer, a remote control apparatus, a satellite radio, a messaging device, or a satellite positioning system receiver.

16. The electronic product of claim 8, wherein the front housing covers a keypad on the rear housing in a closed position and exposes the keypad in an opened position.

17. The electronic product of claim 8, wherein the front housing slides in at least two dimensions when traversing from a closed position to an open position or from the open position to the closed position.

18. The electronic product of claim 8, wherein the fixed axis and the second translating axis are in substantially the same horizontal and vertical planes when the electronic product is in a closed position.

19. The electronic of claim 8, wherein the fixed axis and the first translating axis are in substantially the same horizontal plane when the electronic product is in a closed position and in substantially the same vertical plane when the electronic product is an open position.

20. A method of sliding a first housing portion in two dimensions relative to a second housing portion, comprising the steps of:
coupling a pivot arm between a fixed axis on a first frame of the first housing portion and a first translating axis on a second frame of the second housing portion; and
translating a second translating axis along a first frame guide rail of the first frame as the first translating axis translates along a second frame guide rail of the second frame.
